(19) United States
(12) Patent Application Publication
(10) Pub. No.: US 2023/0131821 A1
(43) Pub. Date: Apr. 27, 2023

(54) HEAT DISSIPATION STRUCTURE AND HIGH THERMAL CONDUCTION ELEMENT

(71) Applicant: Richtek Technology Corporation, Zhubei City (TW)

(72) Inventors: Heng-Chi Huang, Hsinchu (TW); Sheng-Yao Wu, Taoyuan (TW); Chi-Yung Wu, Taoyuan (TW); Yong-Zhong Hu, Hsinchu (TW)

(21) Appl. No.: 17/858,117

(22) Filed: Jul. 6, 2022

(30) Foreign Application Priority Data
Oct. 25, 2021 (TW) 110139562

(51) Int. Cl. H01L 23/495

(52) U.S. Cl. CPC H01L 23/49568; H01L 23/49503; H01L 23/49586

(57) ABSTRACT

A heat dissipation structure, includes: a lead frame, including a high temperature pad and a low temperature pad, the high temperature pad and the low temperature pad being two portions in the lead frame which are separated from each other, wherein a high heat generation component is disposed on the high temperature pad; and a high thermal conduction element, including two sides which are respectively directly connected with the high temperature pad and the low temperature pad, to dissipate the heat energy from the high heat generation component to the low temperature pad.

### CROSS REFERENCE

The present invention claims priority to TW 110139562 filed on Oct. 25, 2021.

### BACKGROUND OF THE INVENTION

### Field of Invention

The present invention relates to a heat dissipation structure, especially a heat dissipation structure with a high thermal conduction element to increase and to even the heat dissipation effect.

### Description of Related Art

For controlling an operating temperature of a chip to be within an acceptable range, a common heat dissipation technology in the prior art is to improve the heat transfer coefficient of the molding compound by mixing with a certain high heat transfer material such as graphene. These mixing formulas have to avoid undesired troubles, such as: melting fluidity downgrade, chemical reaction between or among mixed materials, mold damage and corrosion, excessive change on thermal expansion coefficient, excessive shrinkage during curing the molding compound, other potential undesired material properties, unsteady supply of raw materials, etc.; for these and other considerations, the production of the mixed molding compound usually involves considerable technical difficulties, which leads to a high cost.

FIGS. 1A and 1B show prior art U.S. Pat. No. 9,147,648, in which FIG. 1B shows a cross-section view according to the cross-section line AA in FIG. 1A. This patent provides bridging elements Br1 and Br2 which are disposed on the surface of the dies Ch1 and Ch2, to transfer the heat generated in the dies Ch1 and Ch2 to a circuit board by thermally contacting the surface of the bridging elements Br1 and Br2, and the heat is thus transferred to the outside through the circuit board. However, in this prior art, the bridging elements Br1 and Br2 need to accurately contact the die Ch1 and Ch2, which means that the dimension control of the bridging elements Br1 and Br2 need to be very accurate, so that the heat can be effectively transferred to the circuit board via the bridging element Br1 and Br2.

FIG. 2 shows the technology provided by U.S. Pat. No. 10,438,877, in which a blank portion BL provides structural reinforcement function between the die paddles in the lead frame. The blank portion BL may be conductive or non-conductive, depending on its application requirement. However, the blank portion BL is provided for a reason irrelevant to heat dissipation, and the location of the blank portion BL does not take into consideration whether the adjacent die paddles are at high or low temperature (or, relatively high or low temperature). Therefore, this blank portion BL is not designed to provide any stable thermal conduction function.

To meet the heat dissipation requirement for the dies as well as to solve the drawback of the prior arts, the present invention provides a heat dissipation structure, which can provide a better heat dissipation function with commonly used package materials and lead frame.

### SUMMARY OF THE INVENTION

In one perspective, the present invention provides a heat dissipation structure, which includes: a lead frame, including a high temperature pad and a low temperature pad, the high temperature pad and the low temperature pad being two portions in the lead frame which are separated from each other, wherein a high heat generation component is disposed on the high temperature pad; and a high thermal conduction element, including two sides to respectively directly connect the high temperature pad and the low temperature pad, to dissipate a heat energy from the high heat generation component to the low temperature pad.

In one embodiment, the high thermal conduction element includes a single-material structure or a composite structure.

In one embodiment, the two sides of the high thermal conduction element are connected with a thermal contact surface between the two sides; wherein each side includes a plurality of separated thermal contact points, or, each side includes a thermal contact strip which is separated from a thermal contact strip of the other side.

In one embodiment, the lead frame includes two low temperature pads, wherein the high thermal conduction element thermally contacts the two low temperature pads.

In one embodiment, the two low temperature pads are two portions connected in the lead frame; after packaging the heat dissipation structure with a package material, a connecting part between the two low temperature pads is cut to separate into the two low temperature pads.

In one embodiment, the high temperature pad includes a die paddle.

In one embodiment, the heat energy generated in the high heat generation component is dissipated through the high thermal conduction element to the package material or a periphery of the lead frame.

The heat dissipation structure of the present invention can be used in quad flat no lead package (QFN), quad flat package (QFP), dual in-line package (DIP), small outline package (SOP), small outline transistor (SOT), or system on integrated chip (SOIL).

According to the present invention, the high thermal conduction element is not directly connected to the high heat generation component.

In one embodiment, there is a clearance between the high temperature pad and the low temperature pad in the lead frame below the high thermal conduction element, and a length of the high thermal conduction element is shorter than five times of the clearance width. In another embodiment, the length is longer than three times of the clearance width.

In one embodiment, after packaging the heat dissipation structure with the package material, the package material fills the clearance.

In one embodiment, the heat dissipation structure includes a plurality of the high heat generation components, wherein the high heat generation components are disposed on the high temperature pad, and wherein the high heat generation components do not overlap each other, or at least two of the high heat generation components overlap each other at least partially.

In one embodiment, the high heat generation component thermally contacts the high thermal conduction element directly or indirectly.

In one embodiment, the high heat generation components are not disposed at a same height level . Or, in one embodiment, at least one bridging high heat generation component is disposed on the high thermal conduction element, wherein the high heat generation components and the bridging high heat generation component are not located at the same height level.

In another perspective, the present invention provides a high thermal conduction element, including: a high thermal conductive substrate; and two sides, respectively located on opposite sides of the high thermal conductive substrate, and respectively connected to a high temperature pad and a low temperature pad in a lead frame, to dissipate a heat energy in the high temperature pad to the low temperature pad.

In one embodiment, the two sides of the high thermal conduction element are connected with a thermal contact surface between the two sides; wherein each side includes a plurality of separated thermal contact points, or, each side includes a thermal contact strip which is separated from a thermal contact strip of the other side.

The objectives, technical details, features, and effects of the present invention will be better understood with regard to the detailed description of the embodiments below, with reference to the attached drawings.

### BRIEF DESCRIPTION OF THE DRAWINGS

FIGS. 1A, 1B, and 2 respectively show lead frames and corresponding arrangements according to the prior arts.

FIGS. 3 and 4 respectively show schematic diagrams of the heat dissipation structures according to two embodiments of the present invention.

FIGS. 5A and 5B show analysis results of the heat dissipation structure according to one embodiment of the present invention.

FIGS. 6, 7, 8, and 9 respectively show schematic diagrams of high thermal conduction elements according to several embodiments of the present invention.

FIGS. 10A, 10B, 11A, and 11B show schematic diagrams of the packaging processes of the heat dissipation structures according to two embodiments of the present invention.

FIGS. 12A, 12B, 13A and 13B respectively show schematic diagrams of the heat dissipation structures according to four embodiments of the present invention.

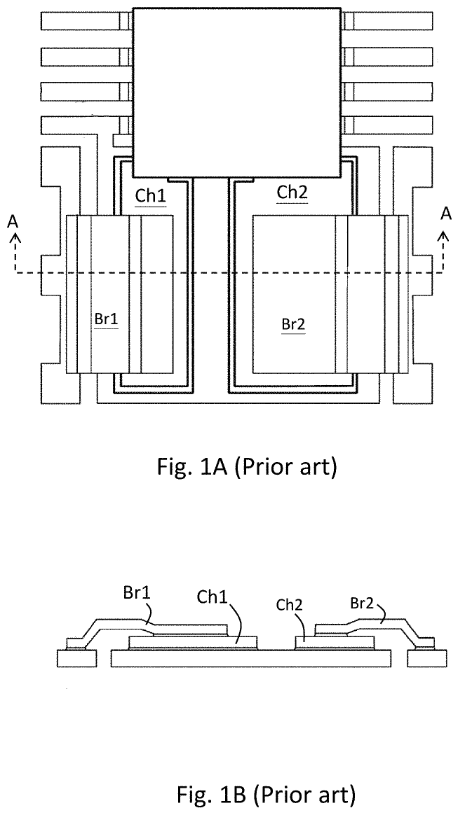

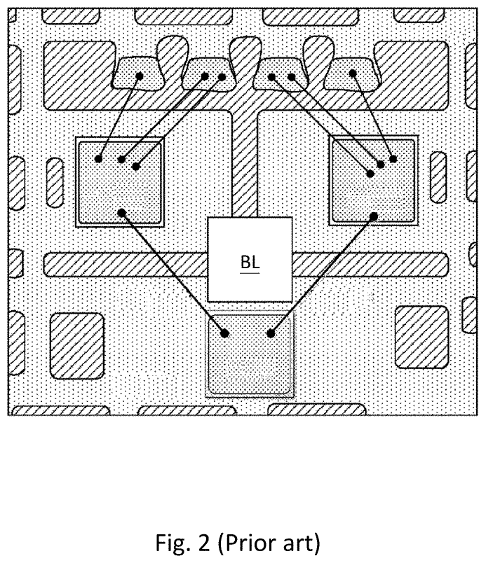

### DESCRIPTION OF THE PREFERRED EMBODIMENTS

The drawings as referred to throughout the description of the present invention are for illustration only, to show the interrelations between the components or units, but not drawn according to actual scale of sizes.

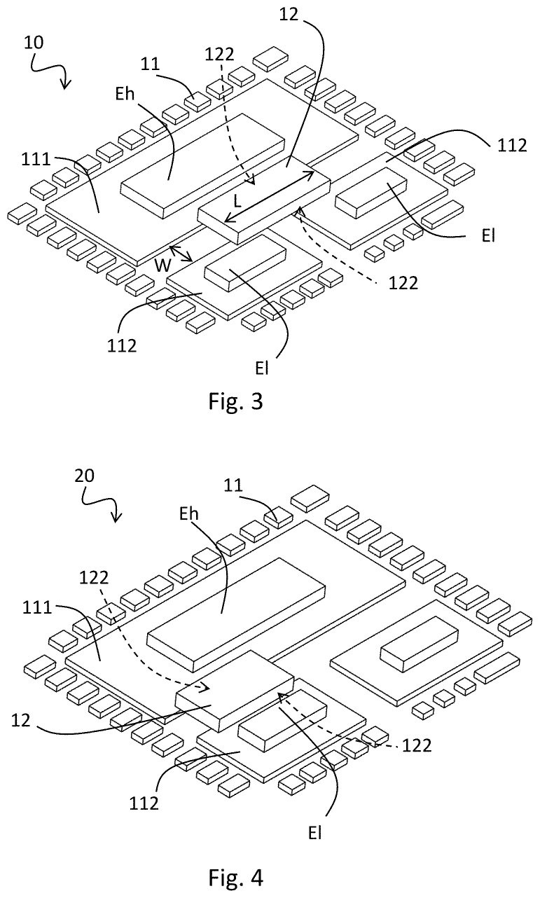

FIGS. 3 and 4 respectively show heat dissipation structures 10 and 20 according to the present invention. The heat dissipation structure 10 or 20 includes: a lead frame 11 and a high thermal conduction element 12. The lead frame 11 includes a high temperature pad 111 and a low temperature pad 112 (FIG. 3 shows two low temperature pads 112, and FIG. 4 shows one low temperature pad 112, indicating that the number of high or low temperature pad(s) can be determined according to application requirement). The high temperature pad 111 and low temperature pad 112 are two separated portions in the lead frame 11, wherein a high heat generation component Eh which may generate high heat during operation can be disposed on the high temperature pad 111; the high heat generation component Eh for example includes a circuit or device which operates in high frequency or consumes high power. Optionally, on the low temperature pad 112 there can be another functional component El, wherein the heat generated by the high heat generation component Eh during operation is higher than the heat generated in the functional component El. The high thermal conduction element 12 has two sides 122, which are respectively directly connected to the high temperature pad 111 and the low temperature pad 112, to dissipate the heat energy in the high heat generation component Eh to the low temperature pad 112. The heat from the high temperature pad 111 is transferred to the low temperature pad 112 through the high thermal conduction element 12 to dissipate the heat, and then the heat is transferred to the periphery of the lead frame 11 or dissipated to the package material covering the heat dissipation structures 10 and 20. In this approach, the present invention provides a better and more even heat dissipation effect by means of the high thermal conduction element 12 which occupies less space than the prior arts, and the present invention does not require using a package material with a high heat transfer property. Therefore, the present invention provides the advantages of flexible choices of the package materials to reduce the manufacturing cost while the heat dissipation performance is satisfactory.

Note that the functional component El disposed on the low temperature pad 112 is optional and can be omitted in a different embodiment.

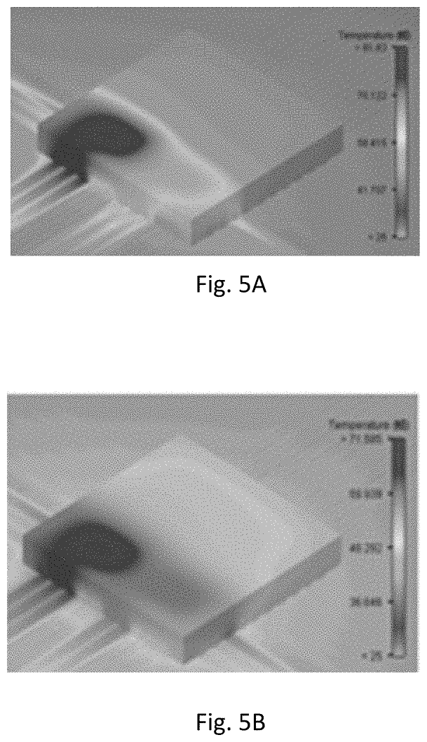

FIGS. 5A and 5B show heat dissipation analyses made by the inventor of the present invention according to the structures of the foregoing embodiments. According to the analysis results, when there is no high thermal conduction element 12 for heat dissipation, the highest temperature of the high temperature pad 111 is as high as 91.8° C. (FIG. 5A) . After disposing the high thermal conduction element 12, the highest temperature of the high temperature pad 111 drops significantly by 20° C. to be 71.5° C. (FIG. 5B). The analysis results shows that the technology provided by the present invention has a significant cooling effect.

Note that, the aforementioned “high temperature” and “low temperature” are relative terms rather than absolute terms, that is, “high temperature” does not mean a temperature higher than a specific temperature, and “low temperature” does not mean a temperature lower than a specific temperature. Rather, they mean that in a heat dissipation structure, the “high temperature” is relatively higher than the “low temperature” when the high heat generation component Eh operates. Similarly, the aforementioned “high heat generation” and “high heat” do not mean generating a heat which is higher than a specific amount, but refer to that the heat generated by the high heat generation component Eh is higher than the heat generated by the functional component El.

In one embodiment, the high temperature pad 111 and the low temperature pad 112 may be disposed at the same height level, or the contact points between the high thermal conduction element 12 and the high temperature pad 111 (and the contact points between the high thermal conduction element 12 the low temperature pad 112) are at the same height level. In this approach, the contact surface of the high thermal conduction element 12 is at the same plane level, so that the manufacturing difficulty is much lower than the case in the prior art wherein there are different height levels for respectively contacting the dies and the lead frame. In addition, according to one embodiment of the present invention, each high heat generation component Eh can be provided with a corresponding high thermal conduction element 12, to achieve a very good heat dissipation effect. As such, the present invention does not need a special high-cost package material, and because the present invention has good heat dissipation effect, heat does not concentrate and accumulate in the high heat generation component Eh to adversely affect the operation and performances of the components.

In the drawings of the foregoing embodiments, only one high thermal conduction element 12 is shown therein. However, the number of the high thermal conduction element (s) according to the present invention is not limited to this number. For example, the lead frame may include two or more high temperature pads and correspondingly two or more high heat generation components respectively disposed on the two or more high temperature pads. In this case, there can be two or more high thermal conduction elements disposed to connect the corresponding low temperature pads to the corresponding high temperature pads, respectively.

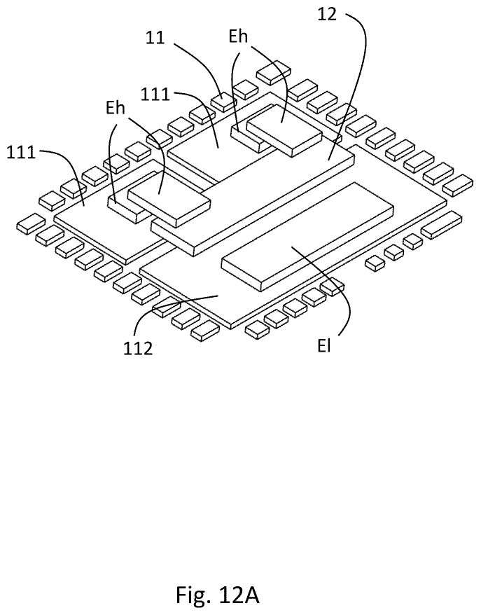

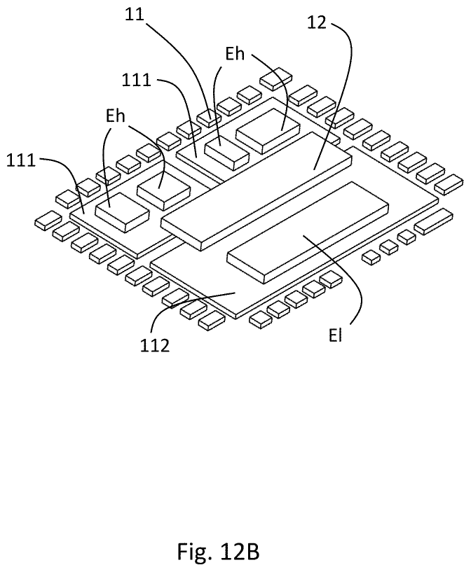

In one embodiment, as shown in FIG. 12A, the lead frame 11 includes two high temperature pads 111, wherein two high heat generation components Eh are disposed on each of the high temperature pad 111, and the two high heat generation components Eh overlap each other partially. In this embodiment, the high heat generation components Eh are not necessarily disposed at the same height level, and the high heat generation components Eh can overlap each other.

In one embodiment, as shown in FIG. 12B, the lead frame 11 includes two high temperature pads 111, wherein two high heat generation components Eh are disposed on each of the high temperature pad 111, and the two high heat generation components Eh do not overlap each other. In this embodiment, the high heat generation components Eh can be disposed at the same height level.

In one embodiment, as shown in FIG. 12A, one of the high heat generation components Eh thermally contacts the high thermal conduction element 12 directly; and the other high heat generation component Eh thermally contacts the high thermal conduction element 12 indirectly.

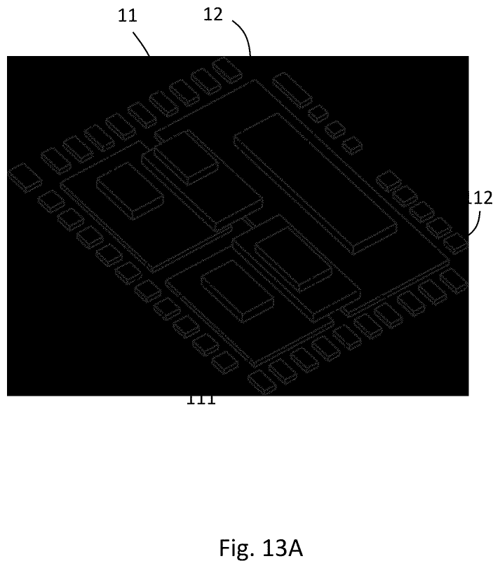

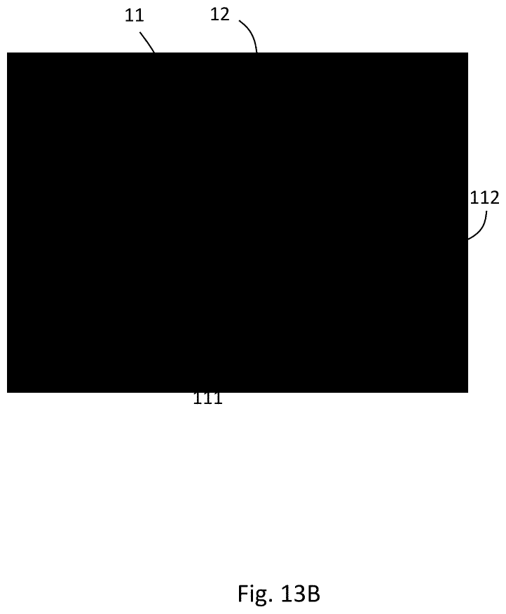

In the embodiment shown in FIG. 12A, the high heat generation components Eh are not disposed at the same height level. Further, in one embodiment, as shown in FIG. 13A, at least one bridging high heat generation component Eb (in FIGS. 13A and 13B, two bridging high heat generation components Eb are shown as examples) is disposed on the high thermal conduction element 12. In these embodiments the bridging high heat generation components Eb are not disposed on the high temperature pad 111. In FIG. 13A, the bridging high heat generation components Eb are respectively disposed on different high thermal conduction elements 12, whereas, in FIG. 13B, the bridging high heat generation components Eb are disposed on one same high thermal conduction element 12. Similar to the high heat generation components Eh, the bridging high heat generation components Eb may generate high heat during operation. In FIGS. 13A and 13B, the high heat generation components Eh and the bridging high heat generation components Eb are not necessarily located at the same height level.

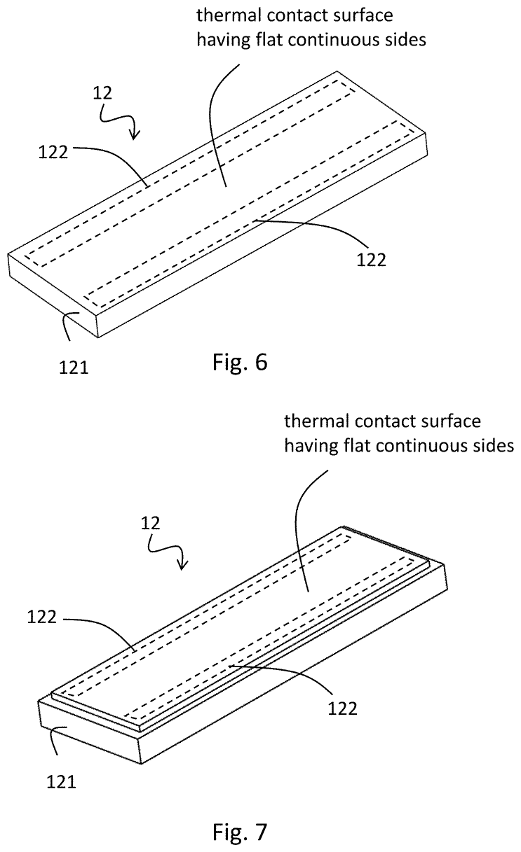

The high thermal conduction element 12 includes a single-material structure (for example, as shown in FIG. 6) or a composite structure (for example, as shown in FIGS. 7, 8, and 9). The single-material structure may be a single-layer structure of high thermal conductive material, and the composite structure may include a composite structure formed by the same or different high thermal conductive materials. In one embodiment, the material of the high thermal conduction element may include a metal material, a silicon-based material, or a thermal conductive insulative material. In one embodiment, the material of the high thermal conduction element may have a linear or nonlinear relationship between working temperature and heat transfer amount. Or, the material of the high thermal conduction element may include a phase change thermal conductive material. Thus, the structure and material of the high thermal conduction element 12 have many options and can be flexibly chosen according to application requirement.

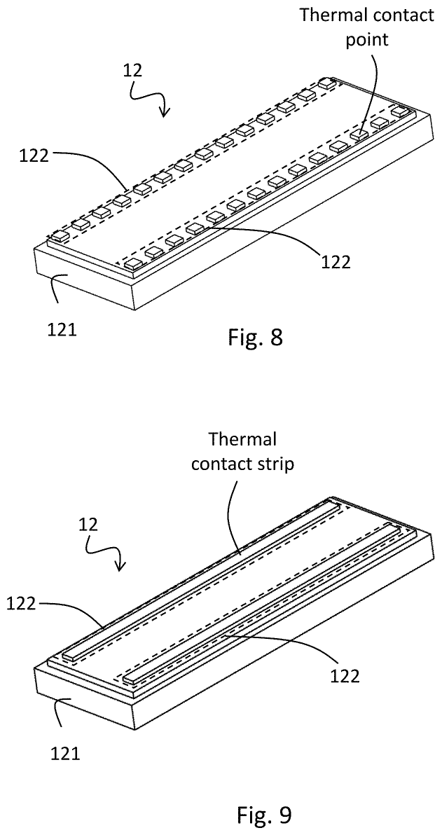

In some embodiments, the two sides 122 of the high thermal conduction element 12 have different designs to directly contact the high temperature pad 111 and the low temperature pad 112, respectively. For example, referring to FIGS. 6 and 7, the high thermal conduction element 12 includes a thermal contact surface which has flat continuous sides (the two sides 122 are two flat continuous sides of the connected thermal contact surface). Or, referring to FIG. 8, the sides 122 of the high thermal conduction element 12 have multiple separated thermal contact points (each side includes multiple separated thermal contact points so each side is not a flat continuous side). Or, referring to FIG. 9, each of the sides 122 of the high thermal conduction element 12 has a thermal contact strip (each side includes a thermal contact strip which is separated from the thermal contact strip of the other side so each side is not a flat continuous side). Or, the sides 122 of the high thermal conduction element 12 may be a combination of different arrangements. For example, one side 122 has a thermal contact strip and the other side has plural separated thermal contact points. When there should not be electrical conduction between the high temperature pad 111 and the low temperature pad 112, the thermal contact surface can be made of a non-conductive material to insulate the continuous sides, the separated thermal contact points or the separated thermal contact points. Or, when an electrical conduction between the high temperature pad 111 and the low temperature pad 112 is needed, the thermal contact surface can be made of a conductive material. In this case, the electrical conduction can provide functions such as common grounding, reducing electro-static charges, etc.

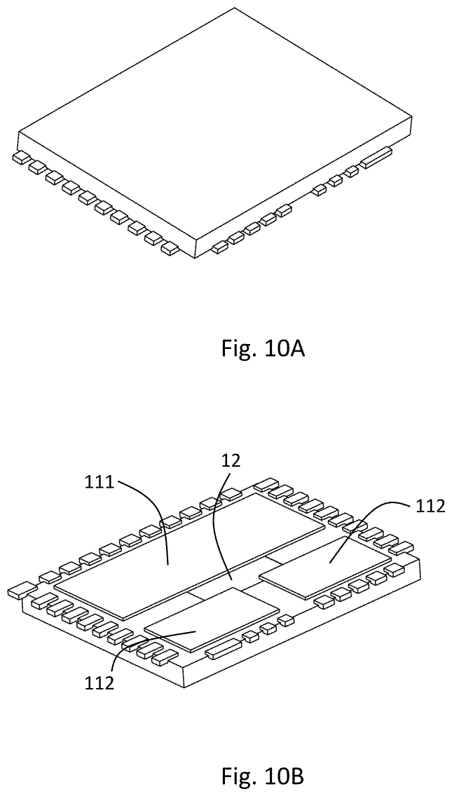

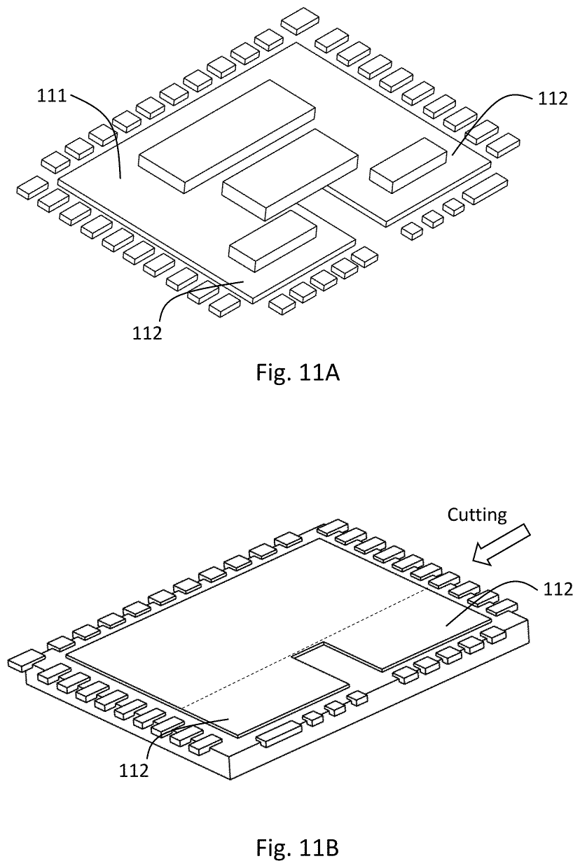

FIG. 3 shows that in one embodiment, the lead frame 11 includes two low temperature pads 112, and the high thermal conduction element 12 thermally contacts the two low temperature pads 112 to increase the heat dissipation range, thus improving the heat transfer effect. The two low temperature pads 112 and their manufacture can be embodied in various ways. Please refer to FIGS. 10A, 10B, 11A and 11B. For example, in one embodiment (FIG. 10A), the two low temperature pads 112 in FIG. 3 are two separated portions in the lead frame 11. After packaging with the package material, it can be seen from bottom view (FIG. 10B) that the two low temperature pads 112 are not connected with each other. In another embodiment (FIG. 11A), the two low temperature pads 112 are two portions of the lead frame 11 but are connected to each other. After packaging with the package material, it can be seen from bottom view (FIG. 11B) that the two low temperature pads 112 are connected to each other. A dashed line shows a cutting line, along which a connecting part is cut to separate the two low temperature pads 112. The cutting for example can be achieved by mechanical cutting, laser cutting or other cutting methods. The mechanical cutting for example can use a blade saw. After cutting, the two low temperature pads 112 are not connected to each other.

In one embodiment, the high temperature pad 111 may include a die paddle in the lead frame. The low temperature pad 112 may include a bond area, another die paddle, a lead finger, or a surrounding frame portion. In one embodiment, the functional component El is disposed on the low temperature pad 112. When the high heat generation component Eh is not in operation so that the temperature of the high temperature pad 111 drops low, the heat transfer direction can be reversed, that is, heat can be transferred from the low temperature pad 112 to the high temperature pad 111. In other words, the heat transfer flow between the high temperature pad 111 and the low temperature pad 112 is bidirectional. The high thermal conduction element 12 can transfer heat bidirectionally depending on the operation state, and is not limited to one-way heat conduction. And, the positions of the high temperature pad 111 and the low temperature pad 112 can be interchanged.

In one embodiment, through the high thermal conduction element 12, the heat generated by the high heat generation component Eh is dissipated to the package material or the periphery (side edges) of the lead frame 11, depending on the location of the high thermal conduction element Eh. For example, when the high temperature pad 111 is located close to a center of the overall package structure, the heat can be dissipated primarily to the package material through the low temperature pad 112. For another example, when the high temperature pad 111 is located close to a side of the overall package structure, the heat can be dissipated primarily to the side of the lead frame 11 through the low temperature pad 112.

The heat dissipation structure of the present invention can be used in quad flat no lead package (QFN), quad flat package (QFP), dual in-line package (DIP), small outline package (SOP), small outline transistor (SOT), or system on integrated chip (SOIL).

According to the present invention, the high thermal conduction element 12 is not directly connected to the high heat generation component Eh. In this way, the heat from the high temperature pad 111 can be dissipated to the low temperature pad 112 first, and then to the package material or the sides of the lead frame 11.

According to the present invention, the packaging method of the heat dissipation structure with the package material is not limited to the aforementioned embodiments of FIGS. 10B and 11B. In one embodiment, when the package material covers the heat dissipation structure, there is a clearance under the high thermal conduction element 12, between the high temperature pad 111 and the low temperature pad 112 in the lead frame 11, and this clearance is also filled by the package material. In FIG. 3, the high thermal conduction element 12 in the heat dissipation structure 10 has a length L, and the lead frame 11 has a clearance which has a clearance width W between the high temperature pad 111 and the low temperature pad 112, wherein the length L extends in a direction which is not parallel to an extending direction of the clearance width W in this embodiment; for example, the extending direction of the length L is perpendicular to the extending direction of the clearance width W. A portion of the clearance between the high temperature pad 111 and the low temperature pad 112 is located under the high thermal conduction element 12. The length L and the clearance width W should preferably have a size relationship, because if length L is too long, after the package material covers the clearance under the high thermal conduction element 12 in a molding process, the package material might not be able to completely fill the clearance below the high thermal conduction element 12. Therefore, in a preferred embodiment, the length L of the high thermal conduction element 12 is shorter than five times of the clearance width W. However, if the component length L is too short, the heat transfer effect of the high thermal conduction element 12 may be adversely impacted. Therefore in one preferred embodiment, the length L is longer than three times of the clearance width W, so that the high thermal conduction element 12 has sufficient length L for heat dissipation.

In one perspective, as shown in FIGS. 3, 4, 6, 7, 8, and 9, the present invention provides a high thermal conduction element 12, including: a high thermal conductive substrate 121; and two side 122, respectively located on opposite sides of the high conductive substrate 121, the two sides 122 (indicated by the dashed lines) are respectively connected to a high temperature pad 111 and a low temperature pad 112 in a lead frame 11 to dissipate the heat generated in the high temperature pad 111 to the low temperature pad 112.

In one embodiment, the high thermal conductive substrate 121 is made of a high heat transfer material which includes a metal material, a silicon-based material, or a thermal conductive material with electrical insulation property. In one embodiment, the material of the high thermal conductive substrate 121 may have a linear or nonlinear relationship between working temperature and heat transfer amount. Or, the material of the high thermal conductive substrate 121 may include a phase change thermal conductive material.

In one embodiment, referring to FIG. 3, the high thermal conduction element 12 and the lead frame 11 on which the high thermal conduction element 12 is disposed, may have a size relation between each other, to provide a suitable space for the package material to fill a clearance below the high thermal conduction element 12 (that is, there is a clearance below the high thermal conduction element 12, between the high temperature pad 111 and the low temperature pad 112). For example, in one embodiment, the length L of the high thermal conduction element 12 is shorter than five times of the clearance width W. In one embodiment, the component length L is longer than three times of the clearance width W, so that the high thermal conduction element 12 has a sufficient length L for effective heat dissipation.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents. cm What is claimed is:

1. A heat dissipation structure, including:
a lead frame, including a high temperature pad and a low temperature pad, the high temperature pad and the low temperature pad being two portions in the lead frame which are separated from each other, wherein a high heat generation component is disposed on the high temperature pad; and
a high thermal conduction element, including two sides to respectively directly connect the high temperature pad and the low temperature pad, to dissipate a heat energy from the high heat generation component to the low temperature pad.

2. The heat dissipation structure according to claim 1, wherein the high thermal conduction element includes a single-material structure or a composite structure.

3. The heat dissipation structure according to claim 1, wherein the two sides of the high thermal conduction element are connected with a thermal contact surface between the two sides; wherein each side includes a plurality of separated thermal contact points, or, each side includes a thermal contact strip which is separated from a thermal contact strip of the other side.

4. The heat dissipation structure according to claim 1, wherein the lead frame includes two low temperature pads, and the high thermal conduction element is in thermal contact with the two low temperature pads.

5. The heat dissipation structure according to claim 4, wherein the two low temperature pads are two portions connected in the lead frame, wherein after packaging the heat dissipation structure with a package material, a connecting part between the two low temperature pads is cut to separate into the two low temperature pads.

6. The heat dissipation structure according to claim 1, wherein the high temperature pad includes a die paddle.

7. The heat dissipation structure according to claim 5, wherein the heat energy generated in the high heat generation component is dissipated through the high thermal conduction element to the package material or a periphery of the lead frame.

8. The heat dissipation structure according to claim 1, wherein the heat dissipation structure is used in quad flat no lead (QFN), quad flat package (QFP), dual in-line package (DIP), small outline package (SOP), small outline transistor (SOT), or system on integrated chip (SOIC).

9. The heat dissipation structure according to claim 1, wherein the high thermal conduction element is not directly connected to the high heat generation component.

10. The heat dissipation structure according to claim 1, wherein there is a clearance between the high temperature pad and the low temperature pad in the lead frame below the high thermal conduction element, and a length of the high thermal conduction element is shorter than five times of the clearance width.

11. The heat dissipation structure according to claim 1, wherein there is a clearance between the high temperature pad and the low temperature pad in the lead frame below the high thermal conduction element, and a length of the high thermal conduction element is longer than three times of the clearance width.

12. The heat dissipation structure according to claim 1, wherein there is a clearance between the high temperature pad and the low temperature pad in the lead frame below the high thermal conduction element, wherein after packaging the heat dissipation structure with a package material, the package material fills the clearance.

13. The heat dissipation structure according to claim 1, including a plurality of the high heat generation components, wherein the high heat generation components are disposed on the high temperature pad, and wherein the high heat generation components do not overlap each other, or at least two of the high heat generation components overlap each other at least partially.

14. The heat dissipation structure according to claim 13, wherein the high heat generation component thermally contacts the high thermal conduction element directly or indirectly.

15. The heat dissipation structure according to claim 13, wherein the high heat generation components are not disposed at a same height level; or
wherein at least one bridging high heat generation component is disposed on the high thermal conduction element, and wherein the high heat generation components and the bridging high heat generation component are not located at a same height level.

16. A high thermal conduction element, including:
a high thermal conductive substrate; and
two sides, respectively located on opposite sides of the high thermal conductive substrate, and respectively connected to a high temperature pad and a low temperature pad in a lead frame, to dissipate a heat energy in the high temperature pad to the low temperature pad.

17. The high thermal conduction element according to claim 16, wherein the two sides of the high thermal conduction element are connected with a thermal contact surface between the two sides; wherein each side includes a plurality of separated thermal contact points, or, each side includes a thermal contact strip which is separated from a thermal contact strip of the other side.

18. The high thermal conduction element according to claim 16, wherein there is a clearance between the high temperature pad and the low temperature pad in the lead frame below the high thermal conduction element, and a length of the high thermal conduction element is short than five times of the clearance width.

19. The high thermal conduction element according to claim 16, wherein there is a clearance between the high temperature pad and the low temperature pad in the lead frame below the high thermal conduction element, and a length of the high thermal conduction element is longer than three times of the clearance width.

20. The high thermal conduction element according to claim 16, wherein there is a clearance between the high temperature pad and the low temperature pad in the lead frame below the high thermal conduction element, wherein after packaging the heat dissipation structure with a package material, the package material fills the clearance.
